(19) United States
(12) Patent Application Publication
(10) Pub. No.: US 2008/0077827 A1
(43) Pub. Date: Mar. 27, 2008

(54) Test method for semiconductor device

(75) Inventor: Satoshi Ishizuka, Kanagawa (JP)

Correspondence Address: MCGINN INTELLECTUAL PROPERTY LAW GROUP, PLLC, 8321 OLD COURTHOUSE ROAD, SUITE 200, VIENNA, VA, 22182-3817, US

(73) Assignee: NEC ELECTRONICS CORPORATION, Kawasaki (JP)

(21) Appl. No.: 11/902,914

(22) Filed: Sep. 26, 2007

(30) Foreign Application Priority Data
Sep. 27, 2006 (JP) 2006-262644

(51) Int. Cl. G11C 29/04; G06F 11/00; G11C 29/12

(52) U.S. Cl. 714/710; 714/E11.001

(57) ABSTRACT

A method for testing a semiconductor device having a detection unit to detect a faulty point by a BIST, a redundant circuit and a replacing unit includes a first step to detect the faulty point by the detection unit under a first test condition and replace the faulty point with the redundant circuit by the replacing unit, a second step to detect the faulty point by the detection unit again under the first test condition for the semiconductor device keeping state after completing the first step, a third step to detect the faulty point by the detection unit under a second test condition for the semiconductor device not having the faulty point detected in the second step where the semiconductor device keeping the state after completing the first step and a fourth step to evaluate the defectiveness of the semiconductor device according to the third step result.

### BACKGROUND OF THE INVENTION

1. Field of the Invention

The present invention relates to a test method of a semiconductor device having a detection unit for detecting a faulty point by a built in self test, a redundant circuit having the same function as when the faulty point is normal and a replacing unit to replace the faulty point with the redundant circuit, where the semiconductor device can be saved by replacing the faulty point with the redundant circuit. More particularly, the present invention relates to a test method of a semiconductor device that is able to electrically save a defective memory device.

2. Description of Related Art

Along with miniaturization of manufacturing process and higher integration of semiconductor integrated circuits, there has been a problem in a semiconductor memory device (hereinafter referred to as a memory device or a memory) of decreasing yield due to manufacturing defective of a memory cell. To deal with such problem, redundancy technique is commonly used in which a redundant memory cell (hereinafter referred to as a redundant cell) is manufactured together with a memory cell to be used in order to replace a defective memory cell with a redundant cell. For such redundancy technique, there is hard redundancy and soft redundancy.

In the hard redundancy, a line connected to a defective memory cell is physically reconnected with a redundant cell using a line changing unit such as fuse. The hard redundancy enables quality assurance by performing a shipping test to the memory that lines have been changed.

In the hard redundancy, fuse group is required for fixing the replacement of a memory cell according to replacement information of the memory cell. Therefore, an area to dispose this fuse group and lines for connecting the fuse with memory cell or redundant cell is needed in a chip. Furthermore, in order to electrically disconnect the fuse, a special device such as laser cutting device is necessary. There are such disadvantages in the hard redundancy although it is possible to improve yield of products by replacing a defective memory cell with a redundant cell.

On the other hand, in the soft redundancy, a BIST (Built In Self Test) is performed before using a memory and based on the result from the BIST, a defective memory cell is replaced with a redundant cell (BISR: Built In Self Repair) by an operation of internal circuit. In the soft redundancy, a BIST is carried out every time the power of the memory is turned on, for example, and if a defective memory cell is detected in the BIST, the defective memory cell is replaced with a redundant cell.

In the soft redundancy, since a circuit for fixing lines physically changed such as fuse as in the hard redundancy, it is not necessary to embed fuse group in a chip. Therefore, when using the soft redundancy, overhead of a redundancy circuit occupying the chip area is smaller than the hard redundancy. Moreover, there is another advantage that a special device such as laser cutting device is not required in the soft redundancy to change lines. Furthermore, if a memory cell is deteriorated in time and the memory cell becomes defective after being shipped, the defective memory cell can be replaced with a redundant cell in the soft redundancy. Thus there is an advantage of attempting to extend product life by using the soft redundancy.

In a common test method of a memory having such soft redundancy function, firstly a BIST is carried out to detect a defective memory cell. Then, based on the BIST result, the defective memory is replaced with a redundant cell (BISR). Subsequently, previously performed BIST is carried out again while maintaining the state after the BISR is carried out. This enables to confirm if the memory after the BISR has been carried out is operating properly.

However, as a memory cell changes its characteristic according to condition for use such as temperature and power conditions, a memory cell operating properly under a certain condition may be defective in a different condition. Therefore, it is not known whether a memory cell replaced under a certain condition by hard or soft redundancy operates properly under a different condition. Especially in the soft redundancy, even if a defective memory cell is repaired under a first condition and also a defective memory cell is repaired under a second condition, the defective memory cells detected under the first and second conditions are not necessarily the same. Generally the soft redundancy detects a defective memory cell before using a memory (first condition) and after repairing the detected defective memory cell, the memory is treated as repaired for at least a certain period of time. The memory may fluctuate temperature and power supply voltage during the use by a user. Therefore, it has been necessary to carry out a BIST when the temperature fluctuates in the state after replacing a memory cell and confirm that the redundant cell is normal after the temperature condition has changed. To deal with this, an example of a test method to a memory having the soft redundancy function is disclosed in Japanese Unexamined Patent Application Publication No. 2001-208798 (Maeno).

A flowchart of a test method according to Maeno is shown in FIG. 5. As shown in FIG. 5, in Maeno, firstly a built in self test (BIST) is carried out to a memory (RAM:Random Access Memory) to obtain failure information and the failure information is compressed to be stored to a register (step S101). Next, evaluate whether the RAM can be repaired by a redundant cell according to the failure information (step S102). Then, a defective cell is replaced with a redundant cell (step S103). After that, a BIST is carried out again to the memory holding the replacement information.

Moreover, in the test method of Maeno, a dummy built in self test is carried out to the memory that steps S101 to S103 are carried out so as to increase the temperature of chip (step S104). At this time, the replacement state performed in step S103 is reset and a redundant cell is not included in the electrically connected memory cell. Then after the step S104, a BIST is carried out and failure information is obtained to compare the failure information with the failure information obtained in the step S101 (step S105). In the test method of Maeno, as a result of the comparison in the step S105, if the failure information in the step S101 is same as the failure information in the step S105, it is determined that no new defective memory cell exists and the chip is non-defective. This ensures that in the test method of Maeno, even when the temperature condition has changed, no new defective memory cell is generated.

However, in the test method to the memory having the soft redundancy function disclosed in Maeno, as the result of the BIST is retained in a register to compare the results of 2 BISTs. Therefore, Maeno has been a problem that the register and a comparator circuit are required and extra circuits not concerning the operation of the memory must be included.

### SUMMARY

In one embodiment, a method for testing a semiconductor device having a detection unit to detect a faulty point by a built in self test, a redundant circuit having a same function in an event the faulty point is normal and a replacing unit to replace the faulty point with the redundant circuit includes a first step to detect the faulty point by the detection unit under a first test condition and replace the faulty point with the redundant circuit by the replacing unit, a second step to detect the faulty point by the detection unit again under the first test condition for the semiconductor device keeping a state after completing the first step, a third step to detect the faulty point by the detection unit under a second test condition for the semiconductor device not having the faulty point detected in the second step where the semiconductor device keeping the state after completing the first step and a fourth step to evaluate whether the semiconductor device is defective or not according to a result of the third step.

In the method for testing a semiconductor device according to the present invention, the detections of the faulty point in the second and third steps are performed while holding the information of the redundant circuit replaced in the first step. At this time, in the third step, the faulty point is detected according to the second test condition which is different from the first condition. That is, with the test method for a semiconductor device according to the present invention, the semiconductor device having a replaced redundant cell is evaluated to be defective or not without comparing the test results.

With the test method of a semiconductor device according to the present invention, a memory and a comparator circuits for carrying out a comparison procedure of BIST results can be eliminated and the circuit size can be reduced.

### BRIEF DESCRIPTION OF THE DRAWINGS

The above and other objects, advantages and features of the present invention will be more apparent from the following description of certain preferred embodiments taken in conjunction with the accompanying drawings, in which:

FIG. 1 is a block diagram of a semiconductor device according to a first embodiment;

FIG. 2 is a block diagram of a memory circuit according to the first embodiment;

FIG. 3 is a flowchart illustrating a test method of a semiconductor device according to the first embodiment;

FIG. 4 is a flowchart illustrating a test method of a semiconductor device according to a second embodiment; and

FIG. 5 is a flowchart illustrating a test method of a semiconductor device according to a prior art.

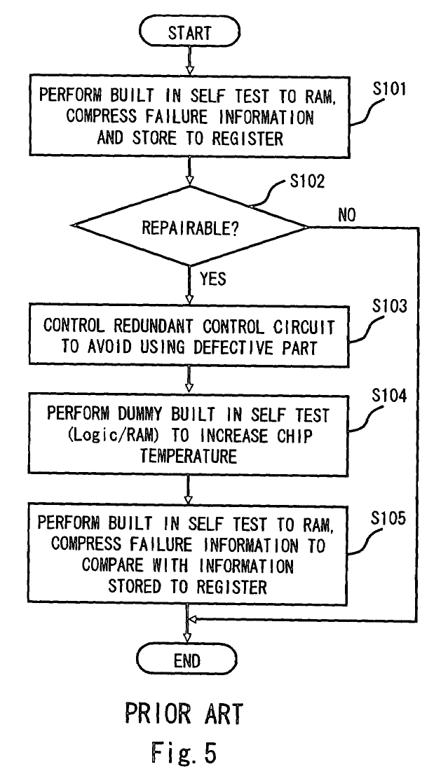

### DETAILED DESCRIPTION OF THE PREFERRED EMBODIMENTS

The invention will be now described herein with reference to illustrative embodiments. Those skilled in the art will recognize that many alternative embodiments can be accomplished using the teachings of the present invention and that the invention is not limited to the embodiments illustrated for explanatory purposes.

### First Embodiment

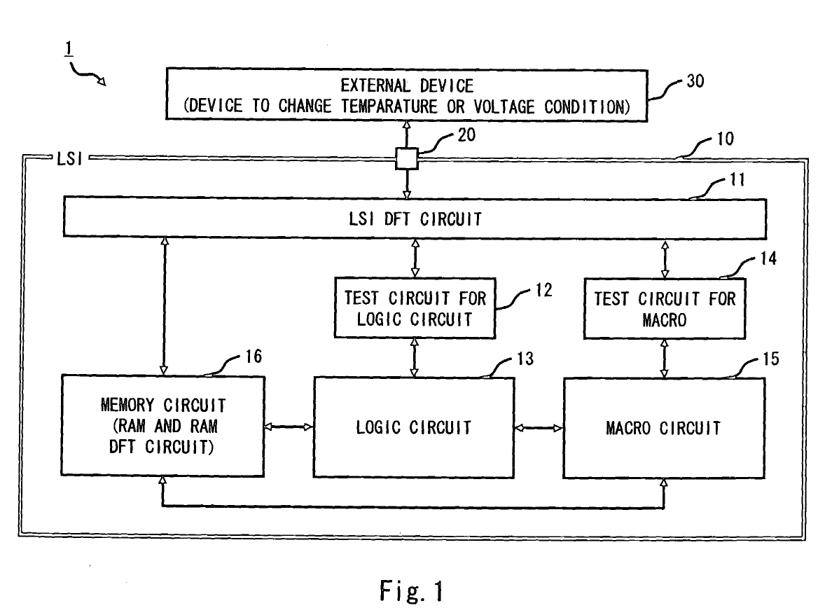

An embodiment of the present invention is described hereinafter in detail with reference to the drawings. A block diagram of a semiconductor device 10 according to this embodiment is shown in FIG. 1. As shown in FIG. 1, the semiconductor device 10 includes a logic circuit 13, a macro circuit 15 and a memory circuit 16 to perform various operations for example. The logic circuit 13 includes a synchronous and asynchronous circuits mounted thereto, for example. In the macro circuit 15, blocks having predetermined functions such as PLL (Phase Locked Loop) and DAC (Digital Analog Converter) circuits are disposed. The memory circuit 16 in this embodiment includes a memory (RAM in FIG. 1) and a test circuit (RAM DFT circuit in FIG. 1), which is a test circuit for the memory. Note that the memory stores and reads out information and the RAM DFT circuit is a test circuit for the memory. Furthermore, in addition to a memory cell with predetermined capacity, the memory of this embodiment includes a redundant circuit (for example redundant cell) operating as a memory cell instead of a faulty point (hereinafter referred to as a defective memory cell). Details of the memory circuit are described later.

Moreover, the semiconductor device 10 includes a LSI DFT circuit 11, a test circuit for logic circuit 12 and a test circuit for macro 14. The LSI DFT circuit 11 is to control the test circuit for logic circuit 12, test circuit for macro 14 and RAM DFT circuit in a test. The test circuit for logic circuit 12 includes a circuit for carrying out a function test for example to a scan chain circuit and the logic circuit 13. That is, the test circuit for logic circuit 12 is used to test the logic circuit 13. The test circuit for macro 14 includes a circuit for carrying out a function test for example to a scan chain circuit and the macro circuit 15. That is, the test circuit for macro 14 is used to test the macro circuit 15.

Furthermore, the LSI DFT circuit 11 communicates with an external device 30 via an external terminal 20 of the semiconductor device 10. The external device 30 is to configure test conditions of the semiconductor device 10, for example, and configures the setting such as operating power supply voltage (hereinafter simply referred to as a power supply voltage) and temperature of the semiconductor device 10. The external device 30 is for example a semiconductor tester capable of configuring power supply voltage and temperature to an object to be measured (semiconductor device 10), for example. At this time, the LSI DFT circuit 11 is an interface between the external device 30 and semiconductor device 10. Note that the external device 30 may directly control the circuits in the semiconductor device 10 without intervening the LSI DFT circuit 11.

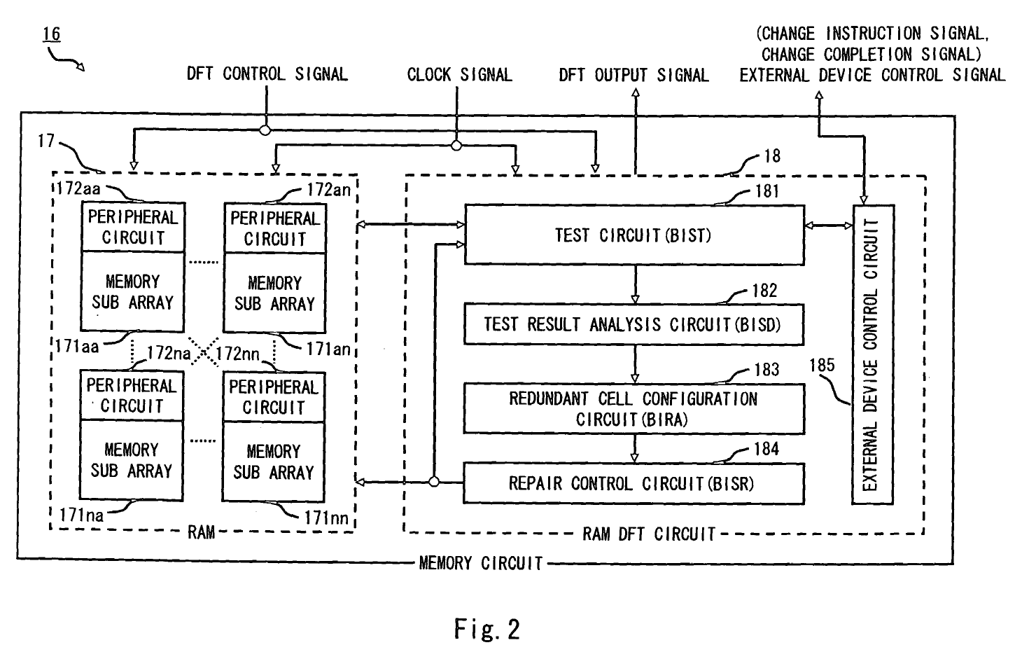

The memory circuit 16 is described in detail here. The block diagram of the memory circuit 16 is shown in FIG. 2. As shown in FIG. 2, the memory circuit 16 includes a RAM 17 and a RAM DFT circuit 18. The RAM 17 includes a memory array having memory sub arrays 171aa to 171nn with a plurality of memory cells and peripheral circuits 172aa to 172nn for the memory sub arrays 171aa to 171nn. In addition to the memory cells used as memory devices, the memory sub arrays 171aa to 171nn include redundant cells that can be replaced with memory cells. Furthermore, in a testing state for example, the peripheral circuits 172aa to 172nn connect the RAM DFT circuit with the memory sub arrays 171aa to 171nn. In a normal state, the peripheral circuits 172aa to 172nn connect the logic circuit 13 or macro circuit 15 with the memory sub arrays 171aa to 171nn. Furthermore, the peripheral circuits 172aa to 172nn change lines when replacing a defective cell with a redundant cell. Line changing is performed according to the control by a repair control circuit 184 which is described later.

The RAM DFT circuit 18 includes a detection unit (for example test circuit) 181, a test result analysis circuit 182, a redundant cell configuration circuit 183, a replacing unit (for example repair control circuit) 184 and a sequence unit (for example external device control circuit) 185.

The test circuit 181 carries out a built in self test (hereinafter referred to as BIST) for each of the memory sub arrays 171aa to 171nn. Additionally, the test circuit 181 outputs the test result as a DFT output signal to outside through the LSI DFT circuit. The test result analysis circuit 182 receives the test result from the test circuit 181 to analyze the test result. This analysis is to determine whether a defective memory cell can be replaced with a redundant cell according to the position and the number of the defective memory cell. The redundant cell configuration circuit 183 is to specifically configure which redundant cell is to be replaced with the defective cell based on the analysis result by the test result analysis circuit 182. The repair control circuit 184 controls the peripheral circuits 172aa to 172nn according to a replacement pattern for the redundant cell that is configured by the redundant cell configuration circuit 183. Moreover, after completing to control line changing for the peripheral circuits 172aa to 172nn, the repair control circuit 184 transmits a replacement completion signal to the test circuit 181 in order to notify the completion. Note that the replacement of a memory cell carried out by the repair control circuit 184 may be referred to as a BISR.

The external device control circuit 185 outputs a change instruction signal for instructing to change the condition to the external device 30 according to a test completion signal output from the test circuit 181. Furthermore, once completing to change the condition by the external device 30, the external device control circuit 185 receives a change completion signal for notifying the completion and outputs a test resume signal for instructing to resume a BIST to the test circuit 181.

To the memory circuit 16, a DFT control signal and a clock signal are input. The DFT control signal is output from the LSI DFT circuit 11 in this embodiment. The DFT control signal is to specify an operation of the memory circuit 16 in a test and for example specifies a pre-shipment test mode and a post-shipment test mode. If the DFT control signal is the pre-shipment test mode, the RAM DFT circuit 18 performs a test operation which is described later. On the other hand, if the signal is the post-shipment test mode, the RAM DFT circuit 18 carries out a BIST, replaces a redundant cell and carries out a BIST again. Moreover, the RAM 17 is configured whether to operate according to the operation of the RAM DFT circuit 18 or the operation of the logic circuit 13 and macro circuit 15 in response to the DFT control signal. A clock signal is clock frequency for the RAM 17 and RAM DFT circuit 18.

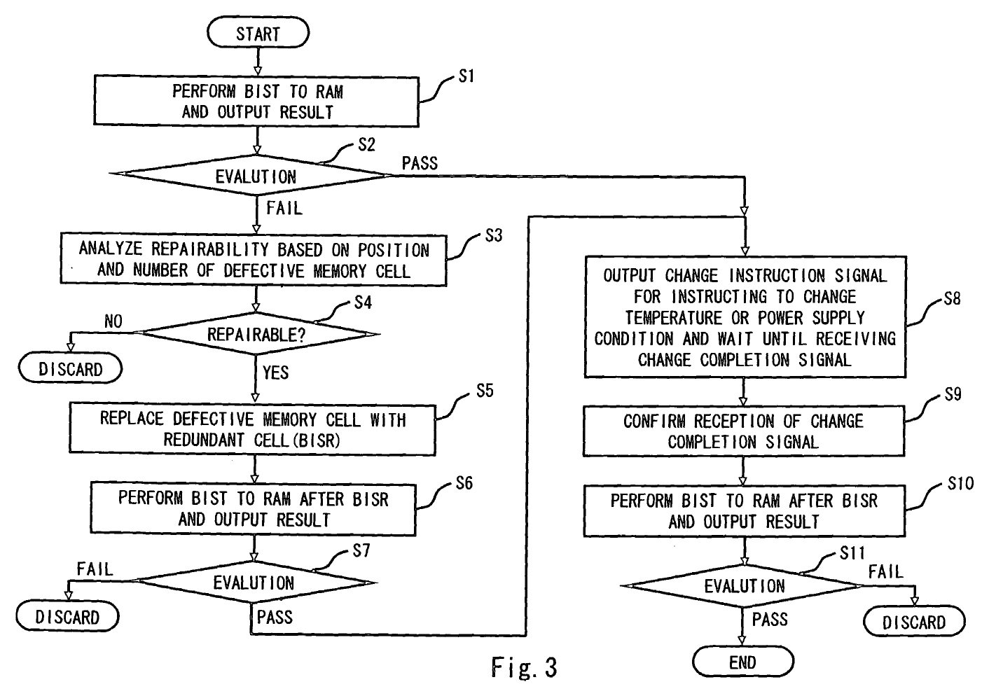

Next, a test method of a semiconductor device according to this embodiment is described. The flowchart of the test method according to this embodiment is shown in FIG. 3. In this embodiment, steps S1 to S5 are carried out as a first step, steps S6 and S7 are carried out as a second step, steps S8 to S10 are carried out as a third step and a step S11 is carried out as a fourth step. These steps are described in more detain hereinafter. Note that in this embodiment, this test is carried out when the DFT control signal is the pre-shipment test mode.

Once the test is started, the test circuit carries out a BIST of the RAM 17 according to the DFT control signal and outputs the result (step S1). A test condition in the step S1 is hereinafter referred to as a first test condition. Then, the external device 30 determines whether the semiconductor device tested according to the result of the BIST is non-defective product or not (step S2). At this time, if there is no defective memory cell in the RAM 17, the process proceeds to the step S8 described later. Meanwhile, if there is a defective memory cell in the RAM 17, the process proceeds to the step S3. In the step S3, the test result analysis circuit 182 analyzes whether the defective memory cell is repairable according to the position and number of the defective memory cell (step S3). If it is determined to be non-repairable as a result of the analysis, the semiconductor device is discarded. In the meantime, if it is determined to be repairable, the process proceeds to the step S5 (step S4). In the step S5, the redundant cell configuration circuit 183 configures the position of a redundant cell and the repair control circuit 184 controls the peripheral circuits 172aa to 172nn according to the configuration. This enables to replace the defective cell with the redundant cell (BISR).

After completing the step S5, a replacement completion signal is transmitted from the repair control circuit 184 to the test circuit 181. According to the replacement completion signal, the test circuit 181 carries out a BIST for the RAM 17 after completing the BISR (step S6). Note that the test condition at this time is the first test condition. After that, based on the result of the BIST, the RAM 17 is evaluated to be non-defective product or not (step S7). If the semiconductor device is defective as a result of the evaluation, the semiconductor device is discarded. On the other hand, if the semiconductor device is non-defective, the process proceeds to the step S8.

Next, after completing the step S7, a test completion signal is output from the test circuit 181 and a change instruction signal is output from the external device control circuit 185 to the external device. Then, according to the change instruction signal, the external device changes the test condition such as power supply and temperature conditions. At this time, the RAM DFT circuit 18 becomes a standby mode while holding the information of the BISR carried out in the step S5 (step S8). Note that the test condition after being changed in the step S8 is hereinafter referred to as a second test condition. Then, after completing to change the condition by the external device 30, the external device 30 outputs a change completion signal. When the external device control circuit 185 receives the change completion signal, the external device control circuit 185 outputs a test resume signal (step S9). In response to the test resume signal, the test circuit 181 carries out a BIST to the RAM 17 after the BISR is carried out and outputs the result (step S10).

Then, according to the result of the step S10, the external device 30 evaluates whether the RAM 17 after the BISR is carried out under the second test condition is defective or not (step S11). If there is a defective memory cell in the RAM 17 as a result of the evaluation, the semiconductor is discarded as a defective product. Meanwhile, if there is no defective memory cell in the RAM 17, it is confirmed that the semiconductor device is non-defective even when the operation condition fluctuates after BIST and the test is terminated.

From the above explanation, with the test method of a semiconductor device according to this embodiment, a BISR is carried out based on the result of the BIST under the first condition and a BIST is carried out under the second condition while keeping the result of the BISR. This enables to evaluate whether the semiconductor device is non-defective without comparing the test results under the first and second test conditions. That is, according to the test method for the semiconductor device of this embodiment, the testing time can be reduced as it is not necessary to compare the test results. Moreover, as there is no need to carry out a BIST every time the test condition is changed, the test time can be reduced also in this point. Additionally, in the semiconductor device of this embodiment, as a memory circuit for holding the BIST result and a comparator circuit for comparing the BIST results are not necessary, the circuit size can be reduced as compared to related art.

Moreover, after replacing a defective memory cell with a redundant cell, it is possible to confirm that the RAM properly operates even when the power supply and temperature conditions are changed. By performing such test, if the operation condition fluctuates in the period of use by a user, it is possible to eliminate the possibility of generating a defective memory cell due to the fluctuation. Specifically, the operation of the RAM can be assured when the operation condition fluctuates in the period of use by a user. That is, with the test method of a semiconductor device according to this embodiment, the reliability of the RAM can be improved.

### Second Embodiment

A test method of a semiconductor device according to a second embodiment is to perform the test in the third step for several times. Moreover, the defective evaluation performed in the fourth step is carried out for the same number of times as the third step in order to evaluate whether the tests are correct or not. Note that in the explanation below, only the part concerning the second embodiment is described.

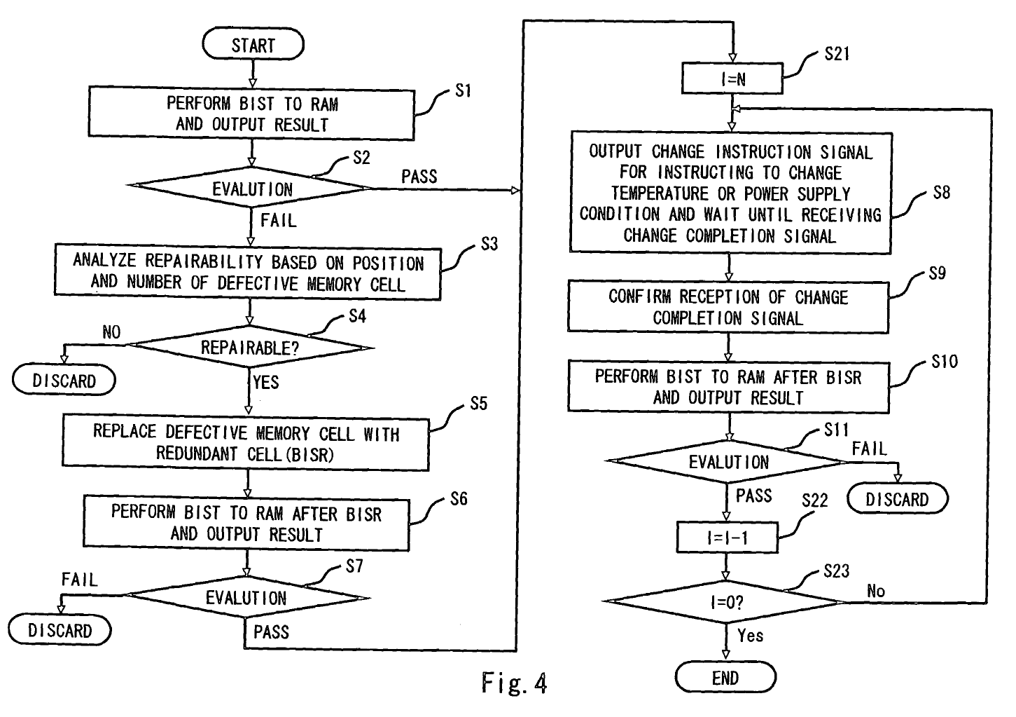

The flowchart for the test method of a semiconductor device according to the second embodiment is shown in FIG. 4. As shown in FIG. 4, the test method of the second embodiment includes a step S21 for configuring the number of execution of the steps S8 to S11 in the flowchart of the test according to the first embodiment, a step S22 for subtracting the number configured in the step S21 every time the steps S8 to S11 are carried out and a step S23 for evaluating whether the number of execution of the steps S8 to S11 has reached the number configured in the Step S21 according to the result of carrying out the step S22.

The test method of the second embodiment is described in more detail. After completing the step S7 and the test process processes to the third step, the number of execution for the third step is configured (step S21). In the example of FIG. 4, the number of execution is “I” and the configured number is indicated by “N”, where I=N.

Next, the third step is carried out in the steps S8 to S11. After that, the value of “I” is subtracted by 1 as in I=I−1 (step S22). Then evaluate whether “I” is “0” (step S23). If the value of “I” is not “0” at this time, the step S8 is carried out again. Note that in the step 8 which is carried out again, the test condition is changed from the third step previously carried out. On the other hand, if I=0 in the step S23, it is evaluated that the number of execution for the third step has reached the number configured in the step S21 and the test is terminated.

From the above explanation, with the test method of a semiconductor device according to the second embodiment, tests of the semiconductor device with a plurality of test conditions can be carried out. For example, the test that changes the power-supply voltage continuously with an intermediate voltage between the upper and lower limits of the voltage defined by the operating power supply voltage of the semiconductor device, the upper limit power supply voltage and lower limit power supply voltage can be executed. By consecutively carrying out tests in this way, it is possible to eliminate memory cells to be defective for example when power supply voltage applied to the semiconductor device fluctuates while being used by a user.

Note that in the test method of a semiconductor device according to the second embodiment, by including the second step carried out in the steps S6 and S7 in one condition of the test carried out in the third step, the second step can be eliminated.

It is apparent that the present invention is not limited to the above embodiment but may be modified and changed without departing from the scope and spirit of the invention.

What is claimed is:

1. A method for testing a semiconductor device having a detection unit to detect a faulty point by a built in self test, a redundant circuit having a same function in an event the faulty point is normal and a replacing unit to replace the faulty point with the redundant circuit, the method comprising:
a first step to detect the faulty point by the detection unit under a first test condition and replace the faulty point with the redundant circuit by the replacing unit;
a second step to detect the faulty point by the detection unit again under the first test condition for the semiconductor device keeping a state after completing the first step;
a third step to detect the faulty point by the detection unit under a second test condition for the semiconductor device not having the faulty point detected in the second step, the semiconductor device keeping the state after completing the first step; and
a fourth step to evaluate whether the semiconductor device is defective or not according to a result of the third step.

2. The method according to claim 1, wherein the third step is carried out a plurality of times.

3. The method according to claim 2, wherein the second step is carried out as a part of the third step carried out a plurality of times.

4. The method according to claim 1, wherein the third step is carried out a plurality of times according to the number of the second test condition in an event the second test condition is the plurality of test conditions.

5. The method according to claim 1, wherein the second test condition is a condition at least one of temperature or power supply voltage condition fluctuates from the first test condition.

6. The method according to claim 1, wherein the built in self test is carried out to a memory device.

7. The method according to claim 1, wherein the built in self test is carried out to a memory macro of a semiconductor device having a memory macro.

8. A semiconductor device tested by the method according to claim 1, comprising a sequence unit to control an execution time of the first to the fourth steps.

9. The semiconductor device according to claim 8, wherein the sequence unit outputs a change instruction signal to instruct to change a condition according to an operation state of the detection unit to a condition changing unit connected externally and upon receipt of a change completion signal from the condition changing unit to notify a completion of changing the condition, the third step is carried out to the semiconductor device.

10. A method for testing a semiconductor device having a detection unit to detect a faulty point by a built in self test, a redundant circuit having a same function in an event the faulty point is normal and a replacing unit to replace the faulty point with the redundant circuit, the method comprising:
executing a first test that detects the faulty point by the detection unit under a first test condition;
replacing the faulty point with the redundant circuit by the replacing unit according to a result of the first test;
executing a second test that detects the faulty point by the detection unit again under the first test condition for the semiconductor device keeping a state where the faulty point is replaced with the redundant circuit;
executing a third test that detects the faulty point by the detection unit under a second test condition for the semiconductor device not having the faulty point detected in the second test, the semiconductor device keeping the state where the faulty point is replaced with the redundant circuit; and
evaluating whether the semiconductor device is defective or not according to a result of the third test.
